(19) United States
(12) Patent Application Publication
(10) Pub. No.: US 2024/0356542 A1
(43) Pub. Date: Oct. 24, 2024

(54) TRENCH GATE TYPE IGBT AND METHOD FOR DRIVING THE SAME

(71) Applicant: WILL SEMICONDUCTOR (SHANGHAI) CO. LTD., SHANGHAI (CN)

(72) Inventors: Tetsuya OKADA, SAITAMA (JP); Hiroki ARAI, SAITAMA (JP)

(21) Appl. No.: 18/213,567

(22) Filed: Jun. 23, 2023

(30) Foreign Application Priority Data
Apr. 19, 2023 (JP) 2023-068361

(51) Int. Cl. H03K 17/16; H01L 29/10; H01L 29/40; H01L 29/417; H01L 29/739

(52) U.S. Cl. CPC H03K 17/168; H01L 29/1095; H01L 29/407; H01L 29/41708; H01L 29/7397

(57) ABSTRACT

[Problem to be solved] To reduce a loss according to an operating condition of high-frequency use or low-frequency use.

[Solution] A trench gate type IGBT includes: a gate trench 120G, which extends from the front surface toward the back surface side of a semiconductor substrate, and causes a current to flow through a channel region formed in the periphery by an applied voltage; a switch trench 120SW, which extends from the front surface toward the back surface side of the semiconductor substrate and has no channel region formed therearound; and a setting terminal for externally controlling the voltage of the switch trench 120SW. A switching between a first state, in which a voltage drop at on-time is relatively small and an energy loss at turn-off time is relatively large, and a second state, in which the voltage drop at on-time is relatively large and the energy loss at turn-off time is relatively small, can be performed, according to a voltage applied to the setting terminal.

### BACKGROUND OF THE INVENTION

### 1. Field of the Invention

Conventionally, an insulated gate bipolar transistor (IGBT) has been widely used as a switching element of a circuit that drives a high-power motor.

For example, Patent document 1 shows that in a trench gate type IGBT, a carrier store (CS) layer for accumulating holes is disposed on the lower side of a channel of the IGBT.

### PRIOR ART DOCUMENTS

### Patent Documents

[Patent document 1] Japanese Patent Laid-Open No. 2005-347289

### SUMMARY OF THE INVENTION

### Problems to be Solved

Here, when a carrier store layer is disposed, a voltage drop (collector-emitter voltage VCE) when an IGBT is turned on can be reduced. That is, the voltage drop due to an on-resistance of the IGBT can be reduced and an energy loss at on-time can be lowered. However, when the IGBT is turned off (switched from on to off), a time required for turn-off becomes longer due to the influence of residual holes, resulting in a higher energy consumption (switching loss).

Thus, the conduction loss and switching loss in the IGBT are in a trade-off relationship, which is determined by a structure when making the IGBT and a concentration of the carrier store layer, and it is impossible for a user to control the trade-off.

### Means to Solve Problems

A trench gate type IGBT according to the disclosure includes:
a semiconductor substrate;
a gate trench, which extends from the front surface toward the back surface side of the semiconductor substrate, and causes a current to flow through a channel region formed in the periphery by an applied voltage;
a switch trench, which extends from the front surface toward the back surface side of the semiconductor substrate and has no channel region formed therearound; and
a setting terminal for externally controlling the voltage of the switch trench; wherein
a switching between a first state, in which a voltage drop at on-time is relatively small and an energy loss at turn-off time is relatively large, and a second state, in which the voltage drop at on-time is relatively large and the energy loss at turn-off time is relatively small, can be performed, according to a voltage applied to the setting terminal.

### Effects

According to the trench gate type IGBT according to the disclosure, by setting the voltage of the switch trench, a reduction in the switching loss or a reduction in the voltage drop at on-time can be selected according to an operating condition (whether an on-off frequency is high or low). Therefore, a trench gate type IGBT with reduced loss according to the operating condition can be obtained.

### BRIEF DESCRIPTION OF THE DRAWINGS

FIG. 1 is a cross-sectional view schematically showing the configuration of a trench gate type IGBT according to an embodiment of the disclosure.

FIG. 2 shows a change in hole density in a depth direction around a switch trench 120SW immediately after the IGBT is turned off, in a case that the switch trench 120SW is set to 0 V or −15 V.

FIG. 3 is a diagram showing changes in VCE and ICE at turn-off time when SW=0 V or −15 V is set for the switch trench 120SW.

FIG. 4 is a diagram showing states of switching loss and conduction loss when a switching frequency is set to 30 kHz, 10 kHz, and 3 kHz.

FIG. 5 is graph showing a relationship between Eoff and VCE (saturation) according to a voltage of SW.

FIG. 6 is a plan view showing an example of a metal layer (single layer) of the IGBT. In this example, the IGBT has a square planar shape.

FIG. 7A is an enlarged schematic view of portion A in FIG. 6.

FIG. 7B is a cross-sectional view taken along line A-A′ in FIG. 7A.

FIG. 7C is a cross-sectional view taken along line B-B′ in FIG. 7A.

FIG. 8 is a plan view showing another example of the metal layer (single layer) of the IGBT.

FIG. 9 is an enlarged view of portion B in FIG. 8.

FIG. 10 is a plan view showing an example of a metal layer (two layers) of the IGBT.

FIG. 11A is an enlarged view of portion B in FIG. 10.

FIG. 11B is a cross section taken along line A-A′ in FIG. 11A.

FIG. 12 is a diagram showing a manufacturing process of the IGBT according to the embodiment of the disclosure.

### PREFERRED EMBODIMENT OF THE PRESENT INVENTION

Hereinafter, embodiments of the disclosure will be described with reference to the drawings. Note that the following embodiments do not limit the scope of the disclosure, and configurations obtained by selectively combining multiple examples are also included in the disclosure.

### “Configuration of IGBT”

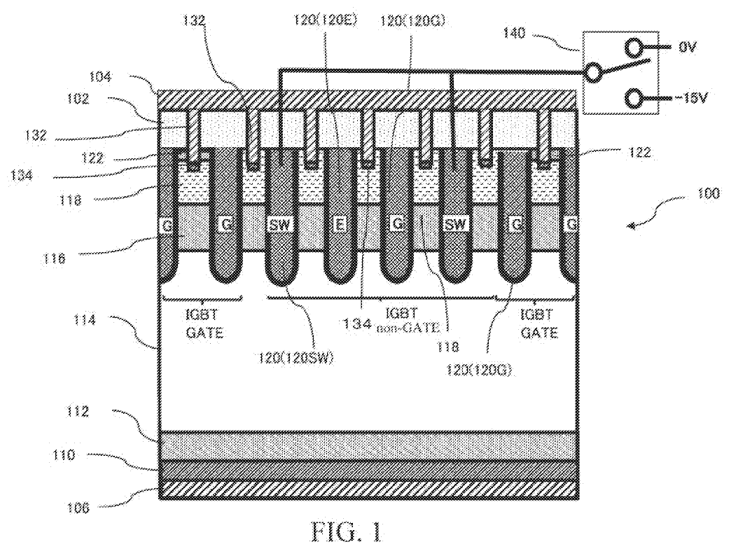

FIG. 1 is a cross-sectional view schematically showing the configuration of a trench gate type IGBT according to an embodiment of the disclosure.

An interlayer insulating film 102 is formed on the front surface of a semiconductor substrate 100. A metal wiring layer is disposed on the interlayer insulating film 102 for necessary electrical connection. In FIG. 1, an emitter pad 104 is shown.

For the semiconductor substrate 100, for example, a silicon (Si) wafer such as a floating zone (FZ) wafer is used, but a silicon carbide (SiC) wafer or the like may alternatively be used. For the interlayer insulating film 102, an insulating material such as silicon oxide is used. For metal wiring, a metal material such as aluminum is usually used.

A collector pad 106 is formed on the back surface of the semiconductor substrate 100. For the collector pad 106, a metal material such as aluminum is usually used.

A P-collector layer 110 of P+ having higher impurity concentration is formed on the back surface portion of the semiconductor substrate on the upper side of the collector pad 106, and a field stop layer 112 of N+ having an impurity concentration higher than that of an N-drift layer 114 described below is formed thereon. These N-type and P-type regions in the semiconductor substrate 100 are formed by doping respective types of impurities. The P-collector layer 110 functions as a collector region, and the field stop layer 112 prevents the spreading of a depletion layer at off-time.

The N-drift layer 114, which is constituted of the semiconductor substrate 100 of N-type, is positioned on the field stop layer 112. The N-drift layer 114 is a body of the semiconductor substrate 100 and functions as a base of a PNP bipolar transistor of the IGBT.

A carrier store layer 116 of N+ having an impurity concentration higher than that of the N-drift layer 114 is disposed on the N-drift layer 114. The carrier store layer 116 has a function of lowering an on-resistance by accumulating holes and lowering VCE, which means a voltage drop at on-time.

A P-body layer 118 of P− having a relatively low impurity concentration is disposed on the carrier store layer 116. The P-body layer 118 functions as an emitter of the PNP bipolar transistor.

In addition, a plurality of trenches 120 are formed downward from the front surface of the semiconductor substrate 100. The trenches 120 extend downward from the front surface of the semiconductor substrate 100 (the lower side of the interlayer insulating film 102) and penetrate the P-body layer 118 and the carrier store layer 116 to reach the N-drift layer 114.

A peripheral wall of the trench 120 is insulated from surroundings by an insulating film that contains, for example, silicon oxide, and the interior of the trench is filled with a conductive material such as polysilicon or the like. This example of the trench includes: a gate trench 120G, the interior of which is connected to a gate electrode (not shown) to form a gate region; and a switch trench 120SW, which is connected to a switch 140. FIG. 1 schematically shows wiring connecting the switch trench 120SW and the switch 140. In this example, a switch SW is a changeover switch and is connected to either 0 V or −15 V. For example, a terminal for the switch 140 may be disposed on the front surface of the semiconductor substrate 100 so that 0 V or −15 V can be switched externally and supplied to the terminal.

In addition, an emitter region 122 of N+ having higher impurity concentration is formed in an area positioned on the front surface side of the P-body layer 118 and adjacent to the gate trench 120G. The emitter region 122 is electrically connected to the emitter pad 104. For example, in a part not shown, the interlayer insulating film 102 is removed and the emitter pad 104 and the emitter region 122 are directly connected.

Accordingly, a region between the emitter region 122 and the carrier store layer 116 functions as a channel of a field effect transistor (FET), and when the FET is turned on, electrons serving as carriers flow from the emitter region into the N-drift layer 114 via the carrier store layer 116.

In addition, a contact 132 from the emitter pad 104 is disposed in a manner of extending to the P-body layer 118 of each mesa section formed between the plurality of trenches 120. Besides, the contact 132 is connected to a (P+) contact region 134 having higher impurity concentration formed in the interior (middle portion) of the P-body layer 118 of the mesa section. Thus, the emitter pad 104 is electrically connected to the contact 132 and the contact region 134, and holes accumulated in the N-drift layer 114 at turn-off time can be extracted to an emitter electrode via the P-body layer 118.

Here, in the embodiment, the contact region 134 is disposed not only for the P-body layer 118 which has the emitter region 122 formed on the front surface portion and functions as a channel, but also for the P-body layer 118 which has no emitter region 122 formed on the front surface portion and does not function as a channel. The contact region 134 is connected to the emitter pad 104 through the contact 132.

Moreover, the interior of the gate trench 120G is connected to a gate electrode disposed separately, and the insulating film of the peripheral wall of the gate trench 120G functions as a gate insulating film.

### “Operation of IGBT”

A positive voltage (for example, 15 V) is applied to the gate trench 120G in a state that a voltage is applied between the collector pad 106 and the emitter pad 104 (for example, 400 V to the collector pad 106 and 0 V to the emitter pad 104). Note that the voltage of 400 V applied to the collector pad 106 mentioned above is merely an example, and the voltage may also be a low voltage such as 10 V or the like depending on an application object.

Accordingly, an inversion layer is generated in a channel around the gate trench 120G to turn on the FET, and an electron current from the emitter region 122 toward the N-drift layer 114 flows. That is, a P region of the P-body layer 118 causes the gate trench 120G to become “+”, and thereby “−” is accumulated at a sidewall of the gate trench 120G, and the channel region is inverted from P-type to N-type, which causes a current to flow here. Accordingly, the PNP bipolar transistor is turned on, holes are supplied from the collector side to the N-drift layer 114, and electrons are supplied from the emitter side, to turn on the IGBT. That is, both the holes and the electrons move, and thus a current from the collector pad 106 toward the emitter pad 104 flows.

In addition, by the field stop layer 112, the spreading of the depletion layer can be suppressed, and thus the overall thickness can be reduced.

In the IGBT according to the embodiment, an emitter trench 120E is disposed in addition to the gate trench 120G, and a region without the emitter region 122 is disposed on the front surface of the P-body layer 118.

That is, a region which is a region of the P-body layer 118 adjacent to the gate trench 120G and has the emitter region 122 existing on the front surface side functions as a channel. This region is referred to as a first mesa region. Therefore, this gate area (IGBT GATE in FIG. 1) functions as the gate of the IGBT.

On the other hand, the P-body layer 118 which has no emitter region 122 on the front surface does not function as a channel even if being adjacent to the gate trench 120G, nor does a region adjacent to the switch trench 120SW function as a channel. This region is referred to as a second mesa region. Therefore, this non-gate area (IGBT non-GATE in FIG. 1) does not function as the gate of the IGBT.

Note that the number of the gate trenches 120G in the gate area and the number of the gate trenches 120G and the emitter trenchs 120E in the non-gate area can be set to any number.

Furthermore, in the IGBT according to the embodiment, by the contact 132, the connection to the P-body layer 118 which does not function as a channel also becomes possible. When the IGBT is turned off, the holes remaining in the N-drift layer 114 can be early extracted to the emitter pad 104. Moreover, the contact 132 is also disposed for the P-body layer 118 which functions as a channel, and the holes can also be extracted at turn-off time here. In addition, although the gate trench 120G is disposed in the non-gate area, the holes are likewise extracted from the P-body layer 118 around the gate trench 120G.

In particular, in the embodiment, the gate trench 120G and the switch trench 120SW are disposed in the non-gate area. Besides, by controlling the voltage of the switch trench 120SW, the state of the holes in the peripheral region can be controlled. For example, by setting the switch trench 120SW to −15 V, the holes can be extracted at a high speed when the IGBT is switched from on to off. On the other hand, by setting the switch trench 120SW to 0 V, a voltage drop (collector-emitter voltage VCE (saturation)) when the IGBT is turned on can be reduced.

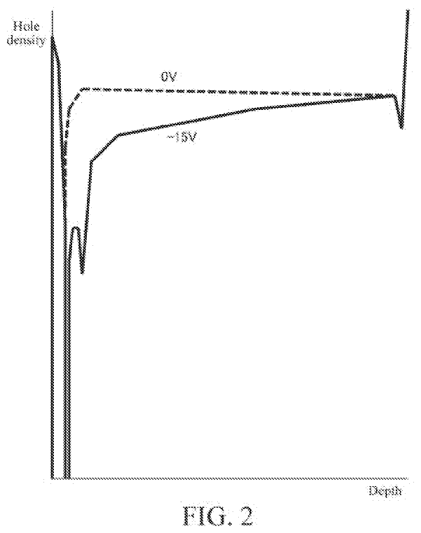

FIG. 2 shows a hole density at turn-on time of the IGBT when the switch trench 120SW is set to 0 V (first state) or −15 V (second state). The solid line illustrates a case of −15 V, and the dashed line illustrates a case of 0 V. In this manner, by setting the switch trench 120SW to −15 V, VCE(sat) becomes higher due to a reduction in the hole accumulation at turn-on time, but Eoff and td(OFF) becomes smaller since it does not take much time to discharge the holes. Therefore, the setting of −15 V is suitable for high frequency operation. In addition, by setting the switch trench 120SW to 0 V, VCE(SAT) becomes lower due to an increase in the hole accumulation, but Eoff and td(OFF) becomes larger since it takes time to discharge the holes. Therefore, the setting of 0 V is suitable for low frequency operation.

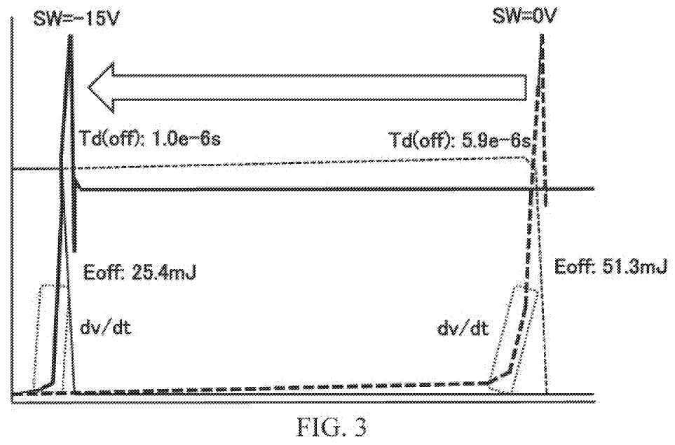

FIG. 3 is a diagram showing changes in VCE (collector-emitter voltage) 0.30 and ICE (collector current) at turn-off time when SW=0 V or −15 V is set for the switch trench 120SW.

In this manner, in a case where SW=0, a delay time Td(off)=5.9e⁻⁶ seconds, whereas in a case where SW=−15 V, Td(off)=1.0e⁻⁶ seconds, and the delay becomes shorter. In addition, a slope dv/dt of VCE becomes larger in a case where SW=−15 V. Therefore, an energy loss (also referred to as switching loss) at turn-off time is 25.4 mJ in a case where SW=−15 V and 51.3 mJ in a case where SW=0. By setting to SW=−15, the holes are extracted quickly, and the switching loss can be suppressed.

On the other hand, in the case where SW=0 V, VCE (saturation) is 0.78 V at a conduction current of 30 A and 1.09 V at a conduction current of 300 A. In the case where SW=−15 V, VCE (saturation) is 1.12 V at a conduction current of 30 A and 1.57 V at a conduction current of 300 A.

A high voltage of VCE (saturation) means that the energy loss (conduction loss) is large when the IGBT is energized.

That is, in the case where SW=0 V, many holes are accumulated and VCE (saturation) is low, but Eoff and Td(off) becomes larger since it takes time to discharge the accumulated holes. On the other hand, in the case where SW=−15 V, less holes are accumulated. Thus, VCE (saturation) becomes higher, but Eoff and Td(off) become smaller since fewer holes are accumulated at turn-off time.

In this manner, in the IGBT, there is a trade-off between VCE (saturation), which corresponds to the loss during conduction, and the switching loss at turn-off time (Eoff). Besides, this trade-off can be adjusted by a carrier concentration in the collector region and a carrier concentration in the carrier store layer, but it is determined by the design of the IGBT. Therefore, a user who uses the IGBT cannot adjust the trade-off at the time of use.

On the other hand, in the IGBT according to the embodiment, the trade-off between reducing the conduction loss and reducing the switching loss can be handled by changing the voltage of the switch trench 120SW.

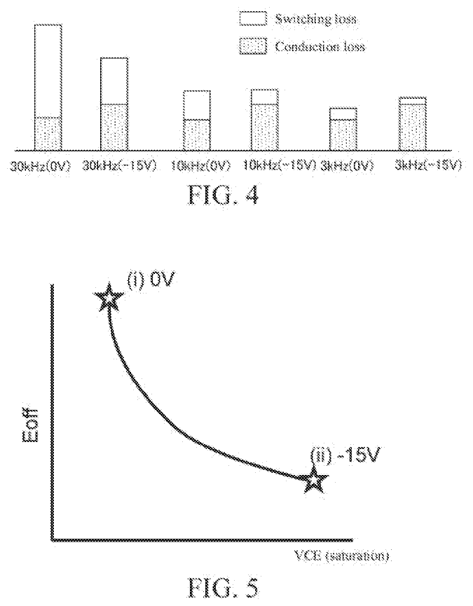

FIG. 4 shows states of switching loss and conduction loss when a switching frequency (on-off frequency) is set to 30 kHz, 10 kHz, and 3 kHz. As can be seen from the figure, at 30 kHz, the losses are less in the case where SW=−15 V, and at 3 kHz, the losses are less in the case where SW=0 V.

In the IGBT according to the embodiment, the user can set the voltage of the switch trench 120SW. That is, the loss can be reduced by changing the characteristics of the IGBT by means of setting SW to 0 V in a case of low frequency and setting SW to −15 V in a case of high frequency.

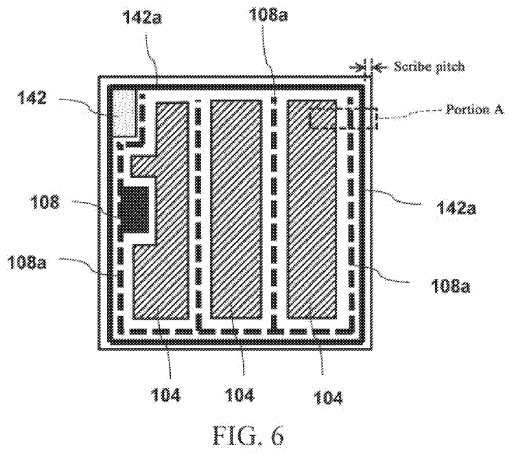

FIG. 5 is graph showing a relationship between the switching loss Eoff and the collector-emitter voltage VCE (saturation) according to the voltage of SW. In this manner, the switching loss Eoff and the collector-emitter voltage VCE (saturation) are determined according to the voltage of SW. Therefore, according to the IGBT according to the embodiment, Eoff and VCE (saturation) can always be set appropriately by setting the voltage of SW according to the switching frequency.

### “Planar and Cross-Sectional Configuration”

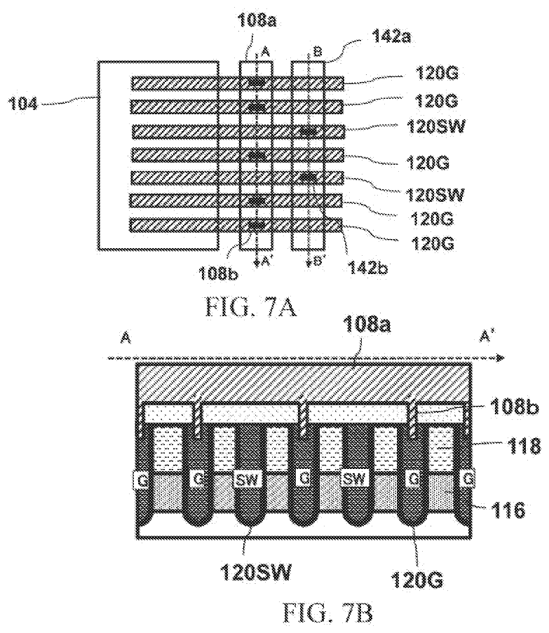

FIG. 6 is a plan view showing an example of a metal layer (single layer) of the IGBT. In this example, the IGBT has a square planar shape.

The square surface is provided with the emitter pad 104, which is divided into three portions in the vertical direction in the figure. The three emitter pads 104 are spaced apart from the periphery portion and a predetermined gap is formed between the three emitter pads 104.

The upper-left corner of the emitter pad 104 on the left side in the figure is recessed, and a switch pad 142 is disposed at this upper-left corner. In addition, a switch wiring 142a having a rectangular shape is disposed along the outer circumference of the front surface of the IGBT in a manner of being connected to the switch pad 142. The switch wiring 142a is disposed inward from the outer circumference by the amount of a scribe pitch. The switch pad 142 functions as a setting terminal for setting the voltage of the switch trench 120SW.

In addition, the left center of the emitter pad 104 on the left is recessed, and a gate pad 108 is disposed here. A gate wiring 108a is connected to the gate pad 108, and extends on both left and right sides, on the lower side, and in the vertical gaps between the three emitter pads 104.

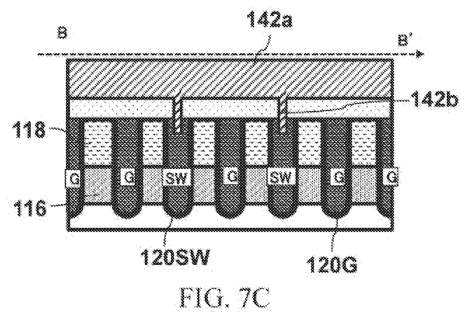

FIG. 7A is an enlarged schematic view of portion A in FIG. 6, showing the structure inside the semiconductor substrate 100. FIG. 7B is a cross-sectional view taken along line A-A′ in FIG. 7A, and FIG. 7C is a cross-sectional view taken along line B-B′ in FIG. 7A.

As shown, the gate trench 120G and the switch trench 120SW extend in the horizontal direction and are positioned below the emitter pad 104, the gate wiring 108a, and the switch wiring 142a extending in the vertical direction.

Besides, the gate trench 120G and the gate wiring 108a are connected through a contact 108b extending downward, and the switch trench 120SW and the switch wiring 142a are connected through a contact 142b extending downward.

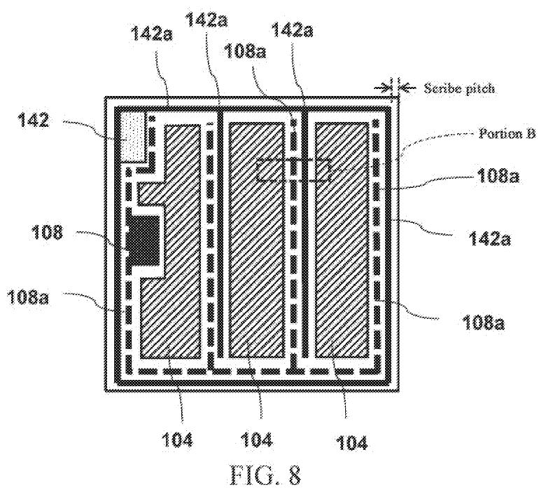

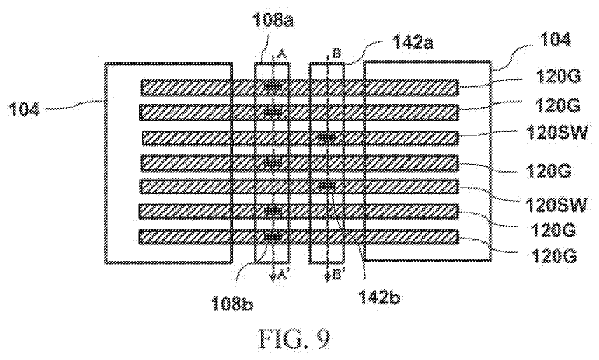

FIG. 8 is a plan view showing another example of the metal layer (single layer) of the IGBT. In addition, FIG. 9 is an enlarged view of portion B in FIG. 8.

In this example, the switch wiring 142a also extends in the gap between the divided emitter pads 104. Thus, the number of the contacts 142b between the switch wiring 142a and the switch trench 120SW can be increased, and an electric field generated by the switch trench 120SW can be set early.

Note that the cross-sectional views taken along line A-A′ and line B-B′ in FIG. 9 are the same as FIG. 7B and FIG. 7C, respectively.

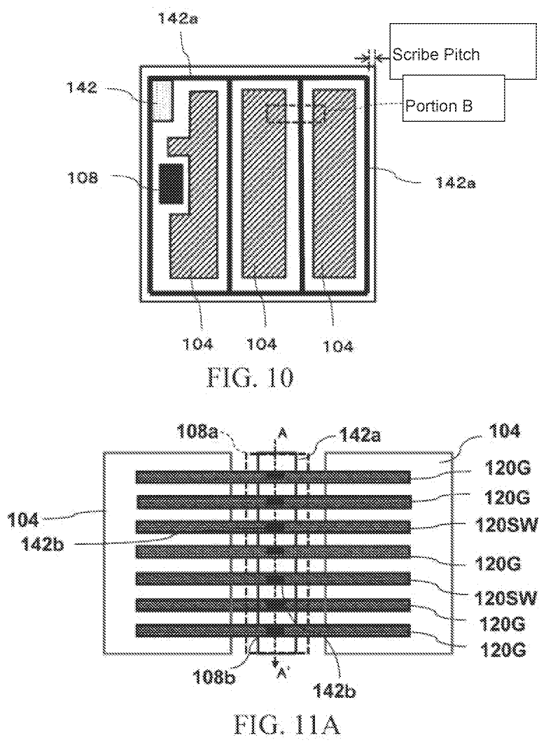

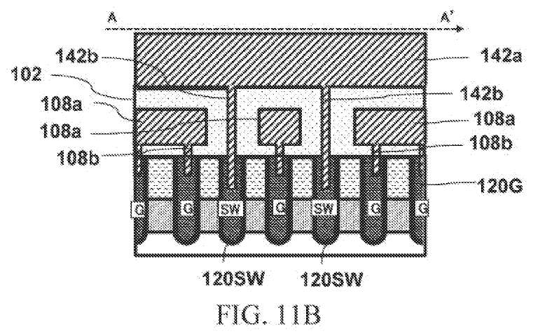

FIG. 10 is a plan view showing an example of a metal layer (two layers) of the IGBT. In addition, FIG. 11A is an enlarged view of portion B in FIG. 10 and FIG. 11B is a cross section taken along line A-A′ in FIG. 11A.

As shown in FIG. 10, the emitter pad 104, the gate pad 108, the switch pad 142, and the switch wiring 142a are present on the front surface of the semiconductor substrate 100, but the gate wiring 108a is not present. As shown in FIG. 11B, the gate wiring 108a is disposed within the interlayer insulating film 102 below the switch wiring 142a. In this manner, by forming the wiring layer as a two-layer structure, an area for disposing a plurality of wirings can be reduced.

### <Manufacturing Process>

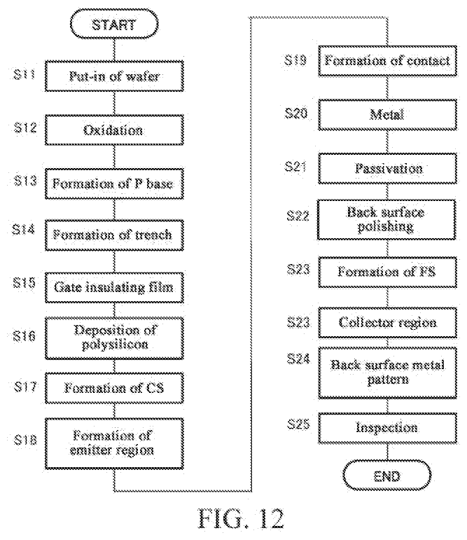

FIG. 12 is a diagram showing a manufacturing process of the IGBT according to the embodiment. First, the semiconductor substrate 100 is prepared and fed into the manufacturing process (S11). As the semiconductor substrate 100, for example, an N-type floating zone (FZ) wafer is used.

First, the front surface side is oxidized to form the interlayer insulating film 102 (S12). Moreover, multiple elements (IGBTs in this case) are produced on a single wafer, and thus it is preferable to perform element separation processing at this stage.

Next, a P-body layer 118 of P+ is formed by doping a P-type impurity from the front surface side (s13). A trench is formed by etching from the front surface side (S14), and an oxide film is formed on a wall surface of the formed trench (S15). If the trench is a gate trench, the oxide film becomes agate insulating film. Then, polysilicon is deposited inside the trench (S16). The polysilicon is conductive.

Next, the carrier store layer (CS layer) 116 is formed by implantation of an N-type impurity (S17). Then, the emitter region is formed by implanting the N-type impurity from the front surface side (S18).

A contact hole is formed by etching from the front surface side, and the contact region 134 is formed by implantation of the P-type impurity. Next, a desired contact hole is formed after the formation of the interlayer insulating film 102. Then, a contact or the like extending over the emitter pad 104, the gate pad 108, the switch pad 142, and the inside of the contact hole is formed by metal deposition (S20). Then, the front surface side is covered with a passivation film (S21).

Next, the back surface side is polished (S22), and the field stop layer 112 and the P-collector layer 110 are sequentially formed from the back surface side (S22, S24). Then, the collector pad 106 is formed by metal deposition (S24).

In this manner, the IGBT is formed and then subjected to various inspections (S25), and thus the manufacturing process ends.

### DESCRIPTION OF THE REFERENCE NUMERALS

100: semiconductor substrate
102: interlayer insulating film
104: emitter pad
106: collector pad
108: gate pad
108a: gate wiring
110: P-collector layer
112: field stop layer
114: N-drift layer
116: carrier store layer
118: P-body layer
120: trench
120E: emitter trench
120G: gate trench
120SW: switch trench
122: emitter region
132: contact
134: contact region
140: switch
142: switch pad
142a: switch wiring
142b: contact

What is claimed is:

1. A trench gate type IGBT, comprising:
a semiconductor substrate;
a gate trench, which extends from the front surface toward the back surface side of the semiconductor substrate, and causes a current to flow through a channel region formed in the periphery by an applied a voltage;
a switch trench, which extends from the front surface toward the back surface side of the semiconductor substrate and has no channel region formed therearound; and
a setting terminal for externally controlling the voltage of the switch trench; wherein
a switching between a first state, in which a voltage drop at on-time is relatively small and an energy loss at turn-off time is relatively large, and a second state, in which the voltage drop at on-time is relatively large and the energy loss at turn-off time is relatively small, can be performed, according to a voltage applied to the setting terminal.

2. The trench gate type IGBT according to claim 1, wherein
the first state is adopted when an on-off frequency is low and the second state is adopted when the on-off frequency is high.

3. The trench gate type IGBT according to claim 2, wherein
the voltage applied to the setting terminal can be changed continuously.

4. A trench gate type IGBT, comprising:
a semiconductor substrate;
an emitter electrode, which is formed on the front surface of the semiconductor substrate;
a collector pad, which is formed on the back surface of the semiconductor substrate;
a P-type P-collector layer, which is formed on the back surface side of the semiconductor substrate on the collector pad;
an N-type N-drift layer, which is positioned on the P-collector layer in the semiconductor substrate;
an N-type carrier store layer, which is formed on the N-drift layer and has an impurity concentration higher than that of the N-drift layer;
a P-type P-body layer, which is formed on the front surface side of the carrier store layer of the semiconductor substrate;
a plurality of gate trenches, which are a plurality of trenches discretely formed from the front surface side of the semiconductor substrate with a mesa section interposed therebetween and extending toward the back surface side to the N-drift layer, and have a gate region formed inside with an insulating film therebetween;
a switch trench, which is a trench discretely formed from the front surface side of the semiconductor substrate with a mesa section interposed therebetween and extending toward the back surface side to the N-drift layer, and is connected to a setting terminal formed inside with an insulating film therebetween and allowing a voltage to be set externally;
an emitter region, which is the mesa section adjacent to the gate trench and is formed on the front surface side of the P-body layer, and is connected to the emitter electrode;
a first mesa region, which is the P-body layer of the mesa section and connected to the emitter electrode through a contact, and functions as a channel by forming the emitter region on the front surface side; and
a second mesa region, which is the P-body layer of the mesa section and connected to the emitter electrode through the contact, and does not function as a channel due to an absence of the emitter region on the front surface side; wherein
the second mesa region is positioned around the switch trench.

5. The trench gate type IGBT according to claim 4, wherein
the first state is adopted when an on-off frequency is low and the second state is adopted when the on-off frequency is high.

6. The trench gate type IGBT according to claim 5, wherein
the voltage applied to the setting terminal can be changed continuously.

7. A method for driving a trench gate type IGBT, the trench gate type IGBT comprising:
a semiconductor substrate;
a gate trench, which extends from the front surface toward the back surface side of the semiconductor substrate, and causes a current to flow through a channel region formed in the periphery by an applied voltage;
a switch trench, which extends from the front surface toward the back surface side of the semiconductor substrate and has no channel region formed therearound; and
a setting terminal for externally controlling the voltage of the switch trench; wherein
when an on-off frequency is low, a first state is adopted in which a voltage drop at on-time is relatively small and an energy loss at turn-off time is relatively large, and
when the on-off frequency is high, a second state is adopted in which the voltage drop at on-time is relatively large and the energy loss at turn-off time is relatively small.

8. The method for driving a trench gate type IGBT according to claim 7, wherein
the first state is adopted when the on-off frequency is low and the second state is adopted when the on-off frequency is high.

9. The method for driving a trench gate type IGBT according to claim 8, wherein
the voltage applied to the setting terminal can be changed continuously.
